(19) United States
(12) Patent Application Publication
(10) Pub. No.: US 2025/0143023 A1
(43) Pub. Date: May 1, 2025

(54) NITRIDE SEMICONDUCTOR LIGHT EMITTING ELEMENT

(71) Applicant: NICHIA CORPORATION, Anan-shi (JP)

(72) Inventor: Nobuyoshi NIKI, Anan-shi (JP)

(73) Assignee: NICHIA CORPORATION, Anan-shi (JP)

(21) Appl. No.: 18/921,406

(22) Filed: Oct. 21, 2024

(30) Foreign Application Priority Data
Oct. 25, 2023 (JP) 2023-183068

(51) Int. Cl. H01L 33/02; H01L 33/32

(52) U.S. Cl. CPC H10H 20/8215; H10H 20/825

(57) ABSTRACT

A nitride semiconductor light emitting element includes a semiconductor structure including an n-side semiconductor layer, a p-side semiconductor layer, and an active layer disposed between the n-side semiconductor layer and the p-side semiconductor layer, and a p-side electrode disposed on the p-side semiconductor layer. The p-side semiconductor layer includes a first semiconductor part that includes, successively from the p-side electrode side, a first layer contacting the p-side electrode and containing Al and a p-type impurity, a second layer containing a p-type impurity and having a lower Al composition ratio and a lower p-type impurity concentration than those of the first layer, and a third layer containing a p-type impurity and having a higher Al composition ratio and a lower p-type impurity concentration than that of the first layer, and a larger thickness than the thicknesses of the first and second layers.

### CROSS-REFERENCE TO RELATED APPLICATION

This application claims priority to Japanese Patent Application No. 2023-183068, filed on Oct. 25, 2023, the disclosure of which is hereby incorporated by reference in its entirety.

### TECHNICAL FIELD

The present disclosure relates to a nitride semiconductor light emitting element.

### BACKGROUND

Japanese Patent Publication No. 2016-178173 discloses a light emitting element formed of a nitride semiconductor including an n-type semiconductor layer, an active layer, and a p-type semiconductor layer.

### SUMMARY

There is a need to improve the emission efficiency of a nitride semiconductor light emitting element.

One object of the present disclosure is to provide a nitride semiconductor light emitting element that can increase emission efficiency.

In order to achieve the objective described above, a nitride semiconductor light emitting element according to the present disclosure includes: a semiconductor structure including an n-side semiconductor layer, a p-side semiconductor layer, and an active layer interposed between the n-side semiconductor layer and the p-side semiconductor layer; and a p-side electrode disposed on the p-side semiconductor layer. The p-side semiconductor layer includes a first semiconductor part that includes a first layer, a second layer, and a third layer, successively from the p-side electrode side. The first layer is in contact with the p-side electrode and contains Al and a p-type impurity, The second layer contains a p-type impurity, and has an Al composition ratio lower than an Al composition ratio of the first layer and a p-type impurity concentration than a p-type impurity concentration of the first layer, The third layer contains a p-type impurity, and has an Al composition ratio higher than the Al composition ratio of the second layer and a p-type impurity concentration lower than the p-type impurity concentration of the first layer. The third layer has a thickness larger than a thickness of the first layer and a thickness of the second layer.

A nitride semiconductor light emitting element of the present disclosure constructed as above can facilitate emission efficiency improvement.

### BRIEF DESCRIPTION OF THE DRAWING

FIG. 1 is a cross-sectional view of the structure of a nitride semiconductor light emitting element according to the present disclosure.

### DETAILED DESCRIPTION

In a nitride semiconductor light emitting element including an n-side semiconductor layer, an active layer, and a p-side semiconductor layer, including an AlGaN layer in the p-side semiconductor layer on which a p-side electrode is disposed, for example, can reduce the absorption by this layer of the light emitted by the active layer to thereby increase the emission efficiency. However, it is more difficult to activate a p-type impurity contained in an AlGaN layer than in a GaN layer. Including a GaN layer in the p-side semiconductor layer on which a p-side electrode is disposed can facilitate the activation of a p-type impurity in the layer, but a GaN layer more readily absorbs the light from the active layer than an AlGaN layer. As a result of extensive studies in consideration of the above, the present inventor found that the employment of a multilayer structure which includes an AlGaN layer containing a relatively large amount of a p-type impurity and a GaN layer for the p-side semiconductor layer on which the p-side electrode is disposed can reduce both the contact resistance between the p-side electrode and the p-side semiconductor layer and the absorption of the light emitted by the active layer.

A nitride semiconductor light emitting element according to the present disclosure includes: a semiconductor structure that has an n-side semiconductor layer, a p-side semiconductor layer, and an active layer interposed between the n-side semiconductor layer and the p-side semiconductor layer; and a p-side electrode disposed on the p-side semiconductor layer. The p-side semiconductor layer includes a first semiconductor part that includes, successively from the p-side electrode side, a first layer, a second layer and a third layer. The fist layer is in contact with the p-side electrode and contains Al and a p-type impurity, The second layer contains a p-type impurity and has an Al composition ratio lower than the Al composition ratio of the first layer and a p-type impurity concentration lower than the p-type impurity concentration of the first layer. The third layer contains a p-type impurity, and has an Al composition ratio higher than the Al composition ratio of the second layer and a p-type impurity concentration lower than the p-type impurity concentration of the first layer. The third layer has a thickness larger than a thickness of the first layer and a thickness of the second layer.

The nitride semiconductor light emitting element of the present disclosure constructed as above can increase emission efficiency.

Specifically, setting the p-type impurity concentration of the first layer that contains Al and a p-type impurity higher than those of the second and third layers can move holes through the p-type impurity level, thereby reducing the contact resistance between the first layer and the p-side electrode and lowering the forward voltage Vf.

Including Al in the first layer can increase the band gap, thereby reducing the absorption of the light emitted by the active layer and increasing the emission output.

Furthermore, the features described below are incorporated in order to increase the emission efficiency in an effective manner.

First, the Al composition ratio of the second layer is set lower than those of the first and third layers in order to facilitate the activation of the p-type impurity contained in the second layer. This can facilitate the supply of holes to the active layer to thereby lower the forward voltage Vf.

Moreover, the degradation of the crystallinity of the second layer is reduced by setting the p-type impurity concentration of the second layer lower than that of the first layer.

Furthermore, the absorption of light by the third layer is reduced by including Al in the third layer, and the degradation of the crystallinity of the third layer is reduced by setting the p-type impurity concentration of the third layer lower than that of the first layer.

Moreover, supplying of holes to the active layer is facilitated by setting the thickness of the third layer containing a p-type impurity larger than the thicknesses of the first and second layers.

A nitride semiconductor light emitting element according to an embodiment will be explained in detail below. In the nitride semiconductor light emitting element of this embodiment, a nitride semiconductor can be any group III-V nitride semiconductors (In_{X}Al_{Y}Ga_{1-X-Y}N (0≤X, 0<Y, X+Y≤1), in which B may be used as a part of a group III element, or may be a mixed crystal semiconductor in which a part of N, a group V element, is replaced with P, As, or Sb. These nitride semiconductor layers can be grown by using any technique, such as metalorganic chemical vapor deposition (MOCVD), hydride vaper phase epitaxy (HVPE), molecular beam epitaxy (MBE), or the like.

### Embodiment

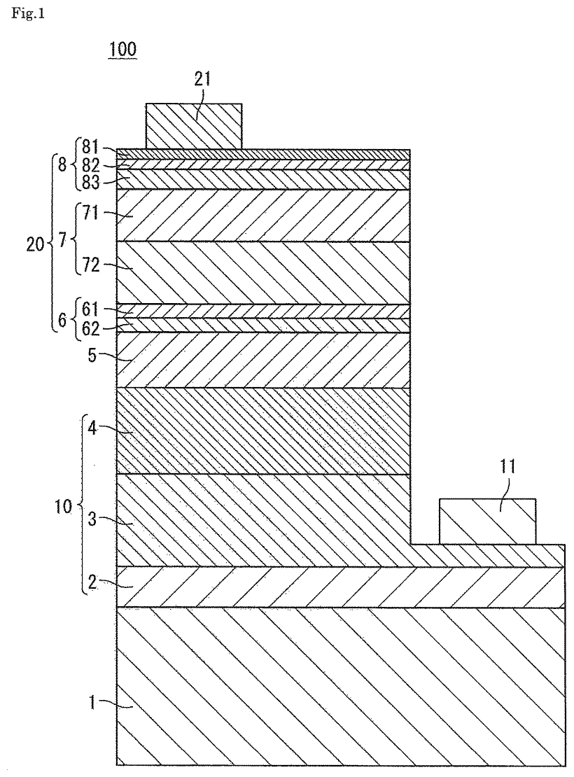

A nitride semiconductor light emitting element according to an embodiment of the present disclosure will be explained below with reference to FIG. 1. The nitride semiconductor light emitting element 100 according to this embodiment includes a substrate 1, an n-side semiconductor layer 10 disposed on the substrate 1, a p-side semiconductor layer 20, an active layer 5 disposed between the n-side semiconductor layer 10 and the p-side semiconductor layer 20, and a p-side electrode 21 disposed on the p-side semiconductor layer 20. The n-side semiconductor layer 10 includes, for example, an underlayer 2, an n-side contact layer 3, and an n-side superlattice layer 4. The p-side semiconductor layer 20 includes a first semiconductor part 8. The p-side semiconductor layer 20 may include a second semiconductor part 7, and may further include a third semiconductor part 6.

The p-side semiconductor layer 20 will be described in detail below, which will be followed by detailed description in succession of the substrate 1, the n-side semiconductor layer 10, the active layer 5, the n-side electrode 11, and the p-side electrode 21.

### P-Side Semiconductor Layer 20

A p-side semiconductor layer 20 has a first semiconductor part 8.

The first semiconductor part 8 includes, successively from the p-side electrode 21 side:
(i) a first layer 81 that is in contact with the p-side electrode 21 and contains Al and a p-type impurity,
(ii) a second layer 82 that contains a p-type impurity and has an Al composition ratio lower than the Al composition ratio of the first layer 81 and a p-type impurity concentration lower than the p-type impurity concentration of the first layer 81, and
(iii) a third layer 83 that contains a p-type impurity and has an Al composition ratio higher than the Al composition ratio of the second layer 82, a p-type impurity concentration lower than the p-type impurity concentration of the first layer 81, and a thickness larger than a thickness of the first layer 81 and a thickness of the second layer 82.

The nitride semiconductor light emitting element including a first semiconductor part 8 that includes the first layer 81, the second layer 82, and the third layer 83 described above can reduce the forward voltage Vf and increase the emission output to thereby improve the emission efficiency.

Here, the first layer 81, the second layer 82, and the third layer 83 are each composed of a nitride semiconductor. The p-type impurity used for the p-side semiconductor layer 20 is, for example, Mg.

The first semiconductor part 8 will be explained in detail below.

### First Semiconductor Part 8

A first semiconductor part 8 includes a first layer 81, a second layer 82, and a third layer 83.

The first layer 81 contains Al and a p-type impurity. Including the first layer 81 contain Al can increase the band gap as compared to a GaN layer to reduce the absorption of light by the first layer 81. This can increase the emission output. For the active layer that emits light having a peak wavelength in a range of 430 nm to 570 nm, for example, a nitride semiconductor containing In such as InGaN or the like is used. Because the band gap of a GaN layer is larger than the band gap of an InGaN layer, the GaN layer presumably has low light absorption to some extent. However, the present inventor found that when a GaN layer contains a p-type impurity and the p-type impurity is activated, the energy gap between the energy level based on the p-type impurity and the level at the lower end of the conduction band becomes narrower than the energy gap between the valence band and the conduction band of the GaN layer itself to increase light absorption. Accordingly, in this embodiment, the light absorption by the first layer 81 is reduced by having the first layer 81 contain Al to make the energy gap between the valence band and the conduction band of the first layer 81 larger than that of the GaN layer.

In the case in which the peak wavelength of the light emitted by the active layer is 430 nm to 570 nm, the Al composition ratio of the first layer 81 is, for example, 3% to 10%, preferably 5% to 9%. This can lessen the forward voltage Vf increase while reducing the occurrence of lattice relaxation between the first layer 81 and the second layer 82 to thereby maintain the crystallinity of the first layer.

The p-type impurity concentration of the first layer 81 is higher than the p-type impurity concentration of the second layer 82 and the p-type impurity concentration of the third layer 83. This can lower the contact resistance between the first layer 81 and the p-side electrode 21 thereby reducing the forward voltage Vf The p-type impurity concentration of the first layer 81 is, for example, 3×10²⁰/cm³ to 1×10²¹/cm³, preferably 4×10²⁰/cm³ to 8×10²⁰/cm³. Setting the p-type impurity concentration of the first layer 81 higher than the p-type impurity concentration of the second layer 82 and the p-type impurity concentration of the third layer 83 and to fall within these ranges can reduce light absorption while lowering the contact resistance between the first layer 81 and the p-side electrode 21.

The thickness of the first layer 81 is, for example, 1 nm to 5 nm, preferably 2 nm to 4 nm. Setting the thickness of the first layer 81 to fall within these ranges can reduce the absorption of the light from the active layer 5 while lowering the contact resistance between the first layer 81 and the p-side electrode 21.

The second layer 82 contains a p-type impurity and has a lower Al composition ratio and a lower p-type impurity concentration than those of the first layer 81.

For the second layer 82 that has a lower Al composition ratio than that of the first layer 81, for example, an AlGaN layer can be used. The second layer 82 may be a nitride semiconductor not containing Al, for example, a GaN layer.

Setting the Al composition ratio of the second layer 82 lower than that of the first layer 81 can achieve a higher activation rate for the p-type impurity contained in the second layer 82 than the first layer 81. This can achieve a high activation rate for the p-type impurity contained in the second layer 82 even when the p-type impurity concentration of the second layer 82 is lower than that of the first layer 81, thereby reducing the forward voltage Vf. Furthermore, setting the p-type impurity concentration of the second layer 82 lower than that of the first layer 81 can suppress the degradation of the crystallinity of the second layer 82.

The Al composition ratio of the second layer 82 is, for example, 0% to 3%, preferably 0% to 2%, more preferably 0%. Setting the Al composition ratio of the second layer 82 to fall within these ranges can increase the activation rate for the p-type impurity contained in the second layer 82, thereby lowering the forward voltage Vf.

The p-type impurity concentration of the second layer 82 is, for example, 1×10²⁰/cm³ to 4×10²⁰/cm³, preferably 1×10²⁰/cm³ to 3×10²¹/cm³. Setting the p-type impurity concentration of the second layer 82 to fall within these ranges can suppress the degradation of the crystallinity of the second layer 82.

The thickness of the second layer 82 is, for example, 3 nm to 10 nm, preferably 4 nm to 8 nm.

The thickness of the second layer 82 in the thickness ranges described above is preferably larger than the thickness of the first layer 81. The second layer 82 has a Al composition ratio lower than the Al composition ratio of the first layer 81 and a higher p-type impurity activation rate than that of the first layer 81. Accordingly, making the thickness of the second layer 82 larger than the thickness of the first layer 81 can increase the supply of holes from the second layer 82 to the active layer 5. This, as a result, can lower the forward voltage Vf while increasing the emission output.

The thickness of the second layer 82 is preferably smaller than the thickness of the third layer 83. As described later, the third layer 83 has an Al composition ratio higher than the Al composition ratio of the second layer 82. The second layer 82 has the Al composition ratio lower than the third layer 83 and relatively easily absorbs light. Thus making the thickness of the second layer 82 smaller than the thickness of the third layer 83 can reduce the light absorption by the second layer 82. The thickness of the second layer 82 is preferably 20% to 40% of the total thickness combining the first layer 81, the second layer 82, and the third layer 83.

The third layer 83 contains a p-type impurity and has the Al composition ratio higher than that of the second layer 82. The third layer 83 has the p-type impurity concentration lower than that of the first layer 81 and the thickness larger than the thickness of the first layer 81 and the thickness of the second layer 82.

The third layer 83 can be made to absorb less light by containing Al as described above. Moreover, the degradation of the crystallinity of the third layer 83 can be suppressed as compared to that of the first layer 81 by setting the p-type impurity concentration of the third layer 83 lower than the p-type impurity concentration of the first layer 81. Furthermore, the supply of holes to the active layer 5 can be facilitated by making the third layer 83 containing a p-type impurity thicker than the thickness of the first layer 81 and the thickness of the second layer 82.

The Al composition ratio of the third layer 83 is, for example, 3% to 10%, preferably 5% to 9%. Setting the Al composition ratio of the third layer 83 to fall within these ranges can reduce the light absorption by the third layer 83 and increase the p-type impurity activation rate in the third layer 83.

The p-type impurity concentration of the third layer 83 is, for example, 1×10²⁰/cm³ to 4×10²⁰/cm³. Setting the p-type impurity concentration of the third layer 83 to this range can facilitate the supply of holes to the active layer 5 while suppressing the degradation of the crystallinity of the third layer 83.

The thickness of the third layer 83 is, for example, 5 nm to 12 nm, preferably 6 nm to 10 nm.

The p-side semiconductor layer 20 preferably further includes one or both of the second semiconductor part 7 and the third semiconductor part 6 described below. This can improve the emission efficiency more effectively.

### Second Semiconductor Part 7

The p-side semiconductor layer 20 preferably includes a second semiconductor part 7 disposed between the first semiconductor part 8 and the active layer 5. The second semiconductor part 7 includes a fourth layer 71 and a fifth layer 72.

The fourth layer 71 is disposed closer to the first semiconductor part 8 than the fifth layer 72 is, and has an Al composition ratio higher than the second layer 82 and an Al composition ratio lower than the third layer 83. For example, for the fourth layer 71, an AlGaN layer can be used.

The fifth layer 72 has the Al composition ratio lower than that of the fourth layer 71. For the fifth layer 72, for example, an AlGaN layer can be used. For the fifth layer 72, a GaN layer which does not contain Al may be used.

The p-type impurity concentration of the fourth layer 71 and the p-type impurity concentration of the fifth layer 72 are lower than the p-type impurity concentration of the third layer 83. The fourth layer 71 and the fifth layer 72 are preferably undoped layers. Here, an undoped layer means a layer which is not intentionally doped with an impurity.

Setting the p-type impurity concentration of the fourth layer 71 and the p-type impurity concentration of the fifth layer 72 lower than the p-type impurity concentration of the third layer 83 can improve the electrostatic withstand voltage characteristics of the nitride semiconductor light emitting element 100. In other words, making the fourth layer 71 and the fifth layer 72 as relatively high electric resistance layers allows the fourth layer 71 and the fifth layer 72 to easily diffuse electric current. This can make it more difficult to form a region in which electric current is concentrated in the p-side semiconductor layer 20, thereby improving the electrostatic withstand voltage characteristics of the nitride semiconductor light emitting element 100. Employing undoped layers for the fourth layer 71 and the fifth layer 72 can further improve the electrostatic withstand voltage characteristics of the nitride semiconductor light emitting element 100.

An AlGaN layer having the Al composition ratio higher than the fifth layer 72 employed for the fourth layer 71 can easily embed V-pits thereby achieving the surface condition of the fourth layer 71 as close to being flat. A semiconductor layer having a high Al composition ratio tends to readily grow in the direction in which V-pits are easily embedded. The crystallinity of the first semiconductor part 8 can be improved by forming the first semiconductor part 8 on a highly flat fourth layer 71. The fifth layer 72 having the Al composition ratio lower than the fourth layer 71 can maintain V-pits of a needed size to thereby improve the emission efficiency as described later. For example, the fifth layer 72 is preferably a GaN layer.

V-pits here are concave-shaped pits formed in a semiconductor layer originating from dislocations occurring when the semiconductor layer is epitaxially grown, for example, dislocations occurring when the n-side superlattice layer 40 described later is grown. V-pits are formed through the active layer 5. In the case in which the p-side semiconductor layer 20 includes a third semiconductor part 6, V-pits are formed through the active layer 5 and the third semiconductor part 6. When viewed from above, the shape of a V-pit is, for example, circular, elliptical, or hexagonal. The diameter of a V-pit is in a range of, for example, 30 nm to 100 nm. AV-pit has a shape, for example, of a cone, elliptical pyramid, or polygonal pyramid in which the diameter increases from the n-side layer 10 side toward the p-side layer 20. By embedding V-pits in the p-side semiconductor layer 20, holes can be supplied to the active layer 5 via the p-side semiconductor layer 20 in V-pits. This can increase the emission efficiency.

The Al composition ratio of the fourth layer 71 is preferably set lower than the Al composition ratio of the first layer 81 and the Al composition ratio of the third layer 83. This makes it possible to embed V-pits effectively while suppressing the rise in the forward voltage Vf In other words, the fourth layer 71 preferably has the high Al composition ratio for embedding V-pits, but the high Al composition ratio raises the concern of increasing the forward voltage Vf attributable to a large band gap difference from that of the fifth layer 72. Accordingly, by setting the Al composition ratio of the fourth layer 71 lower than the Al composition ratio of the first layer 81 and the Al composition ratio of the third layer 83, V-pits can be effectively buried while not allowing the band gap difference between the fourth layer 71 and the fifth layer 72 to become too large. Furthermore, the Al composition ratio of the fourth layer 71 is preferably set lower than the Al composition ratio of the first layer 81 and the Al composition ratio of the third layer 83 while keeping the Al composition ratio difference between the first layer 81 and the third layer 83 to a range of 5% to 10%. This can suppress the forward voltage Vf increase while reducing the occurrence of lattice relaxation between the first layer 81 and the third layer 83 to thereby maintain the crystallinity.

The Al composition ratio of the fourth layer 71 is, for example, 0.5% to 4%.

The p-type impurity concentration of the fourth layer 71 is, for example, 5×10¹⁸/cm³ to 3×10¹⁹/cm³. For example, the fourth layer 71 is an undoped layer.

The thickness of the fourth layer 71 is, for example, 15 nm to 25 nm.

The Al composition ratio of the fifth layer 72 is, for example, 0% to 3%, preferably 0% to 2%, more preferably 0%.

The p-type impurity concentration of the fifth layer 72 is, for example, 5×10¹⁸/cm³ to 3×10¹⁹/cm³. For example, the fifth layer 72 is an undoped layer.

The thickness of the fifth layer 72 is, for example, 15 nm to 50 nm, preferably 20 nm to 40 nm.

In the second semiconductor part 7, the thickness of the fourth layer 71 is preferably larger than that of the third layer 83, and the thickness of the fifth layer 72 is preferably larger than the thickness of the third layer 83. This can enhance the withstand voltage characteristics.

Furthermore, the thickness of the fourth layer 71 is preferably larger than the total thickness combining the first layer 81, the second layer 82, and the third layer 83, i.e., the thickness of the first semiconductor part 8, and the thickness of the fifth layer 72 is preferably larger than the thickness of the fourth layer 71. This can further enhance the electrostatic withstand voltage characteristics.

Here, because the fifth layer 72 has the p-type impurity concentration lower than that of the fourth layer 71 or is an undoped semiconductor layer as described above, the p-type impurity less likely absorbs light. Accordingly, even in the case in which the fifth layer 72 is composed of a GaN layer that has a smaller band gap than an AlGaN layer, for example, the light absorption by the fifth layer 72 can be reduced as compared to the case of using a GaN layer which has a relatively high p-type impurity concentration.

### Third Semiconductor Part 6

The p-side semiconductor layer 20 preferably includes a third semiconductor part 6 disposed between the second semiconductor part 7 and the active layer 5. The third semiconductor part 6 includes a sixth layer 61 disposed closer to the second semiconductor part 7, and a seventh layer 62 disposed closer to the active layer 5.

The Al composition ratio of the sixth layer 61 is higher than both the Al composition ratio of the first layer 81 and the Al composition ratio of the third layer 83.

Moreover, the p-type impurity concentration of the seventh layer 62 is higher than the p-type impurity concentration of the sixth layer 61.

The inclusion of a sixth layer 61 that has an Al composition ratio higher than those of the first layer 81 and the third layer 83 can facilitate the trapping of electrons in the active layer 5. The Al composition ratio of the sixth layer 61 is, for example, 25% to 45%, preferably 30% to 40%. Setting the Al composition ratio of the sixth layer 61 to fall within these ranges can facilitate electron trapping.

The thickness of the sixth layer 61 is, for example, 3 nm to 7 nm. Setting the thickness of the sixth layer 61 to fall within this range can facilitate electron trapping.

The inclusion of a seventh layer 62 having a p-type impurity concentration higher than that of the sixth layer 61 can increase the supply of holes to the active layer 5. The p-type impurity concentration of the seventh layer 62 is, for example, 5×10¹⁹/cm³ to 3×10²⁰/cm³.

The seventh layer 62 preferably has a low Al composition ratio for efficiently activating the p-type impurity. The Al composition ratio of the seventh layer 62 is 0% to 3%, preferably 0% to 2%, more preferably 0%.

The p-type impurity concentration of the seventh layer 62 is preferably lower than the p-type impurity concentration of the first layer 81, which allows the seventh layer 62 to have good crystallinity.

The thickness of the seventh layer 62 is, for example, 2 nm to 6 nm.

The emission efficiency can be increased by composing the p-side semiconductor layer 20 with multiple layers having various functions, and setting the parameters, such as the composition and the thickness, of the individual layers to effectively demonstrate their functions as described above.

The constituents of the nitride semiconductor light emitting element 100 of the present disclosure other than the p-side semiconductor layer 20 will be explained below.

### Substrate 1

For a substrate 1 (see FIG. 1), for example, an insulating substrate such as sapphire having C-plane, R-plane, or A-plane, any of which is a principal face, or spinel (MgAl₂O₄) can be used. For the substrate 1, SiC (including 6H, 4H, or 3C), ZnS, ZnO, GaAs, Si, or the like may be used. For example, a semiconductor structure is disposed on a substrate 1 made of sapphire having C-plane as a principal face. The substrate 1 does not have to be included.

### N-Side Semiconductor Layer 10

As shown in FIG. 1, the n-side semiconductor layer 10 includes, successively from the substrate side 1, an underlayer 2, an n-side contact layer 3, and an n-side superlattice layer 4. The n-side semiconductor layer 10 includes at least one n-type semiconductor layer containing an n-type impurity. For the n-type impurity, for example, Si, Ge, or the like can be used.

The underlayer 2 is disposed between the substrate 1 and the n-side contact layer 3. Disposing an underlayer 2 can form a high crystallinity n-side contact layer 3 on the upper face of the underlayer 2. The underlayer 2 is, for example, AlGaN or GaN. A buffer layer may further be included between the underlayer 2 and the substrate 1. The buffer layer is for reducing lattice mismatch between the substrate 1 and the underlayer 2, and can be, for example, an undoped AlGaN or GaN.

The n-side contact layer 3 is disposed on the upper face of the underlayer 2, and contains an n-type impurity in at least one portion. As shown in FIG. 1, the n-side electrode 11 described later is disposed on the upper face of the n-side contact layer 3. The n-side contact layer 3 is preferably doped with a relatively high concentration n-type impurity for supplying electrons from the n-side electrode 11 to the active layer 5. The n-type impurity concentration of the n-side contact layer 3 can be set, for example, to 6×10¹⁹/cm³ to 1×10¹⁹/cm³. The n-side contact layer 3 can be composed of GaN, AlGaN, AlN, or InGaN, for example. The n-side contact layer 3 may be a multilayer structure formed, for example, by alternately stacking an undoped GaN and a GaN doped with an n-type impurity. The n-side contact layer 3 is, for example, 5 μm to 20 μm in thickness.

The n-side superlattice layer 4 is disposed on the upper face of the n-side contact layer 3. Disposing an n-side superlattice layer 4 can reduce the lattice relaxation between the n-side contact layer 3 and the active layer 5, thereby allowing the active layer 5 to have good crystallinity. The n-side superlattice layer 4 has a structure in which semiconductor layers having different lattice constants are alternately stacked. The n-side superlattice layer 4 includes, for example, n pairs of an undoped InGaN layer and an undoped Gan Layer. The number of pairs provided in the n-side superlattice layer 4 is set, for example, in a range of 10 to 40, preferably 15 to 35, more preferably 25 to 35.

### Active Layer 5

An active layer 5 can be, for example, a single quantum well structure including a well layer and a barrier layer, or a multiple quantum well structure.

A well layer is composed of a nitride semiconductor containing In, for example. In the case of using In_{X}Al_{Y}Ga_{1-X-Y}N (0≤X, 0<Y, X+Y≤1) as a well layer, for example, the peak wavelength of the light from the nitride semiconductor light emitting element can be made to fall in a range of 430 nm to 570 nm by using a predetermined In composition ratio x.

A barrier layer in the active layer 5 is composed of a material that can trap carriers in a well layer. A barrier layer is composed of GaN, InGaN, or AlGaN having a larger band gap than that of a well layer, for example. Barrier layers are positioned on both sides of a well layer, and one or both of those barrier layers provided on both sides may be composed of two or more layers having different band gaps. Furthermore, the barrier layers may contain an n-type impurity. For example, having the barrier layers contain an n-type impurity can reduce the forward voltage Vf of the nitride semiconductor light emitting element 100.

### N-Side Electrode 11

An n-side electrode 11 is disposed in contact with the n-side contact layer 3. For the n-side electrode 11, for example, a metal material including Ti, Rh, Au, Pt, Al, Ag, or Ru can be used.

### P-Side Electrode 21

A p-side electrode 21 is disposed on the p-side semiconductor layer 20 and in contact with the first layer 81. For the p-side electrode 21, for example, a metal material including Ti, Rh, Au, Pt, Al, Ag, or Ru can be used. The p-side electrode 21 may include, in addition to these metal materials, a light transmissive conducting layer formed of ITO (indium tin oxide), IZO (indium zinc oxide), ZnO, In₂O₃, or the like. In the case in which the p-side electrode 21 includes a light transmissive conducting layer, the light transmissive conducting layer is preferably disposed in contact with the first layer 81.

The nitride semiconductor light emitting element of the present disclosure constructed as above can increase emission efficiency.

What is claimed is:

1. A nitride semiconductor light emitting element comprising:
a semiconductor structure comprising an n-side semiconductor layer, a p-side semiconductor layer, and an active layer disposed between the n-side semiconductor layer and the p-side semiconductor layer; and
a p-side electrode disposed on the p-side semiconductor layer; wherein:
the p-side semiconductor layer comprises a first semiconductor part that comprises, successively from a p-side electrode side, a first layer, a second layer, and a third layer;
the first layer is in contact with the p-side electrode and contains Al and a p-type impurity;
the second layer contains a p-type impurity, and has an Al composition ratio lower than an Al composition ratio of the first layer and a p-type impurity concentration lower than a p-type impurity concentration of the first layer;
the third layer contains a p-type impurity, and has an Al composition ratio higher than the Al composition ratio of the second layer and a p-type impurity concentration lower than the p-type impurity concentration of the first layer; and
the third layer has a thickness larger than a thickness of the first layer and a thickness of the second layer.

2. The nitride semiconductor light emitting element according to claim 1 wherein: the thickness of the second layer is larger than the thickness of the first layer.

3. The nitride semiconductor light emitting element according to claim 1, wherein:
the p-side semiconductor layer further comprises a second semiconductor part disposed between the first semiconductor part and the active layer;
the second semiconductor part comprises, successively from a first semiconductor part side, a fourth layer and a fifth layer;
the fourth layer has an Al composition ratio higher than the Al composition ratio of the second layer and lower than the Al composition ratio of the third layer;
the fifth layer has an Al composition ratio lower than the Al composition ratio of the fourth layer; and
a p-type impurity concentration of the fourth layer and a p-type impurity concentration of the fifth layer are both lower than the p-type impurity concentration of the third layer.

4. The nitride semiconductor light emitting element according to claim 2, wherein:
the p-side semiconductor layer further comprises a second semiconductor part disposed between the first semiconductor part and the active layer;
the second semiconductor part comprises, successively from a first semiconductor part side, a fourth layer and a fifth layer;
the fourth layer has an Al composition ratio higher than the Al composition ratio of the second layer and lower than the Al composition ratio of the third layer;
the fifth layer has an Al composition ratio lower than the Al composition ratio of the fourth layer; and
a p-type impurity concentration of the fourth layer and a p-type impurity concentration of the fifth layer are both lower than the p-type impurity concentration of the third layer.

5. The nitride semiconductor light emitting element according to claim 3, wherein:
a thickness of the fourth layer and a thickness of the fifth layer are both larger than the thickness of the third layer.

6. The nitride semiconductor light emitting element according to claim 4, wherein:
a thickness of the fourth layer and a thickness of the fifth layer are both larger than the thickness of the third layer.

7. The nitride semiconductor light emitting element according to claim 3, wherein:
the p-side semiconductor layer further comprises a third semiconductor part disposed between the second semiconductor part and the active layer;
the third semiconductor part comprises a sixth layer and a seventh layer;
the sixth layer has an Al composition ratio higher than the Al composition ratio of the first layer and the Al composition ratio of the third layer; and
the seventh layer is positioned closer to the active layer than the sixth layer is, and has a p-type impurity concentration higher than the p-type impurity concentration of the sixth layer.

8. The nitride semiconductor light emitting element according to claim 4, wherein:
the p-side semiconductor layer further comprises a third semiconductor part disposed between the second semiconductor part and the active layer;
the third semiconductor part comprises a sixth layer and a seventh layer;
the sixth layer has an Al composition ratio higher than the Al composition ratio of the first layer and the Al composition ratio of the third layer; and
the seventh layer is positioned closer to the active layer than the sixth layer is, and has a p-type impurity concentration higher than the p-type impurity concentration of the sixth layer.

9. The nitride semiconductor light emitting element according to claim 7 wherein:
the p-type impurity concentration of the seventh layer is lower than the p-type impurity concentration of the first layer.

10. The nitride semiconductor light emitting element according to claim 8 wherein:
the p-type impurity concentration of the seventh layer is lower than the p-type impurity concentration of the first layer.

11. The nitride semiconductor light emitting element according to claim 1 wherein:
the thickness of the second layer is 20% to 40% of the total thickness combining the first layer, the second layer, and the third layer.

12. The nitride semiconductor light emitting element according to claim 2 wherein:
the thickness of the second layer is 20% to 40% of the total thickness combining the first layer, the second layer, and the third layer.

13. The nitride semiconductor light emitting element according to claim 3 wherein:
the Al composition ratio of the fourth layer is lower than the Al composition ratio of the first layer and the Al composition ratio of the third layer; and
an Al composition ratio difference between the first layer and the third layer is 5% to 10%.

14. The nitride semiconductor light emitting element according to claim 4 wherein:
the Al composition ratio of the fourth layer is lower than the Al composition ratio of the first layer and the Al composition ratio of the third layer; and
an Al composition ratio difference between the first layer and the third layer is 5% to 10%.
